(19) United States
(12) Patent Application Publication
(10) Pub. No.: US 2006/0001494 A1
(43) Pub. Date: Jan. 5, 2006

(54) Cascaded locked-loop circuits deriving high-frequency, low noise clock signals from a jittery, low-frequency reference

(76) Inventors: Bruno Garlepp, San Jose, CA (US); Michael Sobelman, Campbell, CA (US)

Correspondence Address: SILICON EDGE LAW GROUP, LLP, 6601 KOLL CENTER PARKWAY, SUITE 245, PLEASANTON, CA, 94566, US

(21) Appl. No.: 11/021,003

(22) Filed: Dec. 23, 2004

Related U.S. Application Data
(60) Provisional application No. 60/585,110, filed on Jul. 2, 2004.

(51) Int. Cl. H03L 7/00

(52) U.S. Cl. 331/2

(57) ABSTRACT

An integrated circuit includes clock synthesis and distribution circuitry that includes cascaded PLLs to deliver low-noise transmit and receive clock signals that can be tuned over a broad range of frequencies. The clock synthesis circuitry derives a low-jitter intermediate reference clock signal IRClk from a relatively noisy, low-frequency external reference clock signal using a first PLL stage with a high-Q voltage-controlled oscillator (VCO). This first PLL stage has a low loop bandwidth, and thus acts as a low-pass filter (LPF) to remove the reference clock jitter. The low jitter intermediate clock signal is distributed to one or more second PLL stages that derive higher frequency transmit and/or receive clock signals from the intermediate clock signal. Each second PLL stage includes a low-Q VCO that exhibits a considerable tuning range to support a number of transmit and receive data rates. The second PLL stages are adapted to provide high loop bandwidth to minimize phase noise introduced by the low-Q VCO.

### FIELD OF THE INVENTION

The present invention relates generally to the field of communications, and more particularly to high speed electronic signaling within and between integrated circuit devices.

### BACKGROUND

Integrated circuits (ICs) experience process, voltage, and temperature variation that render difficult the task of integrating a sufficiently clean and stable clock source to support high-speed communication. ICs therefore rely on specialized external clock sources to reference timing. One such clock source is often shared by components in a system, such as by a number of ICs on a printed circuit board, or number of printed circuit boards in a backplane communication system. Precision external clock sources that employ crystal oscillators provide relatively stable clock frequencies. Temperature compensation circuitry is typically added to improve frequency stability over a range of temperatures. The frequency stability of temperature compensated crystal oscillators (TCXOs) may approach 0.1 PPM.

The speed at which high-performance ICs transmit and receive data is ever increasing. Unfortunately, distributed reference clock sources are not keeping pace with the circuits that use them. Part of the problem is a legacy issue, as system designers grow accustomed to using well characterized, stable, and relatively inexpensive clock sources. Routing constraints and system noise exacerbate the problem.

ICs that require higher clock frequencies than are provided by external oscillators can be adapted to multiply a reference clock signal to create an internal reference clock signal of the desired frequency. However, in the process of multiplying the reference clock signal, its jitter (phase noise) can be passed along as ever higher frequencies (multiplication factors) are required, so the jitter of the resulting multiplied clock passed from the reference clock becomes a greater percentage of the system unit interval. There is therefore a need for a clocking architecture that derives high-frequency, low-jitter clock signals from relatively low frequency reference clock sources. Such clock signals could be used as transmit and receive clock signals, for example. Ideally, such a clocking architecture would produce an output clock signal that exhibits a considerable tuning range to provide compatibility with communication schemes that employ different clock rates.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 depicts an integrated circuit (IC) 100 in accordance with one embodiment. IC 100 includes cascaded first and second phase-locked loops (PLLs) 105 and 110.

FIG. 2 depicts an integrated circuit (IC) 200 that includes clock synthesis and distribution circuitry in accordance with one embodiment that delivers low-noise transmit and receive clock signals that can be tuned over a broad range of output frequencies.

FIG. 3 depicts an IC 300 in accordance with another embodiment. IC 300 is similar to IC 200 of FIG. 2.

FIG. 4 depicts an IC 400 in accordance with an embodiment that employs a two-stage clocking architecture of the type described above in connection with FIGS. 2 and 3.

FIG. 5 depicts an IC 500 in accordance with an embodiment extended to derive 750 MHz, 1.5 GHz, and 3 GHz clock signals for SATA interfaces.

### DETAILED DESCRIPTION

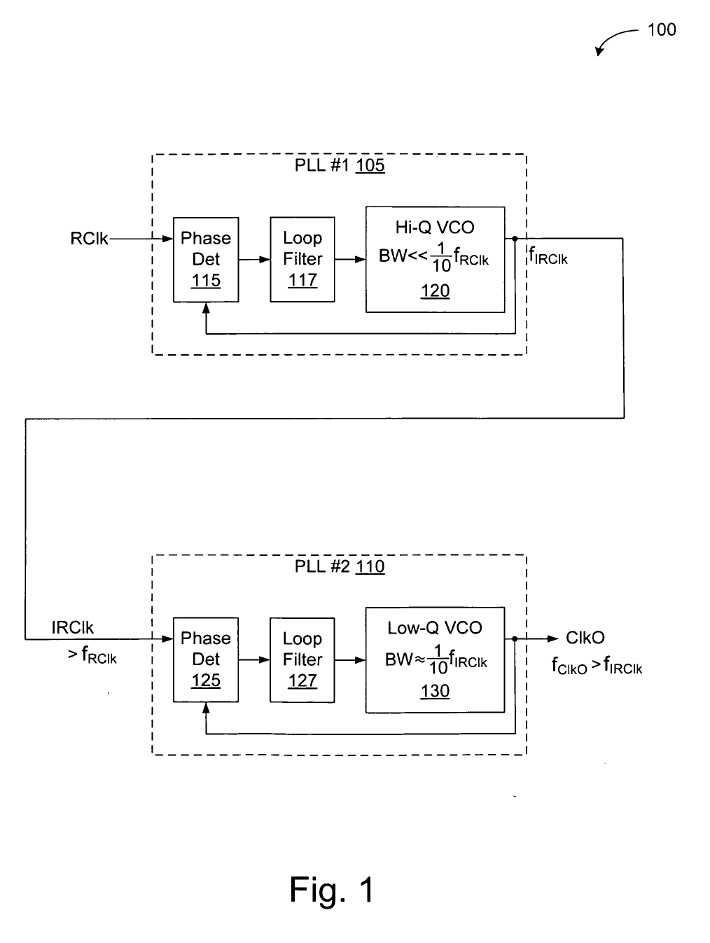

FIG. 1 depicts an integrated circuit (IC) 100 in accordance with one embodiment. IC 100 includes cascaded first and second phase-locked loops (PLLs) 105 and 110. PLL 105 includes a phase detector 115, a loop filter 117, and a voltage-controlled oscillator (VCO) 120; PLL 110 includes a phase detector 125, a loop filter 127, and a VCO 130. PLL 105 derives a low-jitter intermediate reference clock signal IRClk from what may be a relatively noisy, low-frequency external reference clock signal RClk using VCO 120, a high-Q oscillator. PLL 105 has a low loop bandwidth, and thus acts as a low-pass filter (LPF) to remove jitter from reference clock signal RClk. In this example, the loop bandwidth of PLL 105 is substantially less than ten percent of the reference clock frequency. PLL 105 may be adapted to multiply the reference clock frequency by some factor so that the relatively low jitter intermediate clock signal IRClk is of a higher frequency than the reference clock signal (i.e., F_{IRClk} may be greater than F_{RClk}).

PLL 110 derives an output clock signal (e.g., a transmit and/or receive clock signal) from intermediate reference clock signal IRClk. In comparison with VCO 120, VCO 130 is a relatively low-Q oscillator that exhibits a considerable tuning range to support a number of output clock frequencies. PLL 110 is adapted to provide high loop bandwidth to minimize phase noise introduced by low-Q VCO 130.

Reference clock RClk and various components of PLLs 105 and 110 introduce undesirable phase noise. The clock multiplication and distribution system of IC 100 addresses these noise sources so that output clock signal ClkO exhibits low jitter over a broad frequency range. The first PLL 105 exhibits a narrow loop bandwidth and employs a high-Q VCO. PLL 105 thus acts as a low-pass filter to reject input phase noise, while the high-Q VCO introduces little additional noise. The second-stage PLL 110 exhibits much higher loop bandwidth than PLL 105 and employs a relatively low-Q VCO that can be tuned over a relatively broad frequency range. The wide loop bandwidth of PLL 110 enables it to reject much of its own VCO-induced noise. Also helpful, prior multiplication of the reference clock RClk by PLL 105 limits the degree to which PLL 110 is required to multiply the intermediate reference clock, and consequently the amount of VCO noise introduced by PLL 110. The characteristics of PLLs 105 and 110 (e.g., the loop bandwidth, VCO quality, and frequency control) may be tuned to achieve a preferred balance of reference-clock and VCO noise rejection to obtain an optimal noise transfer function.

PLLs 105 and 110 are illustrated in connection with basis elements of PLLs that are well known to those of skill in the art. Many implementations, variations, and combinations of those elements may be used, some of which are detailed below.

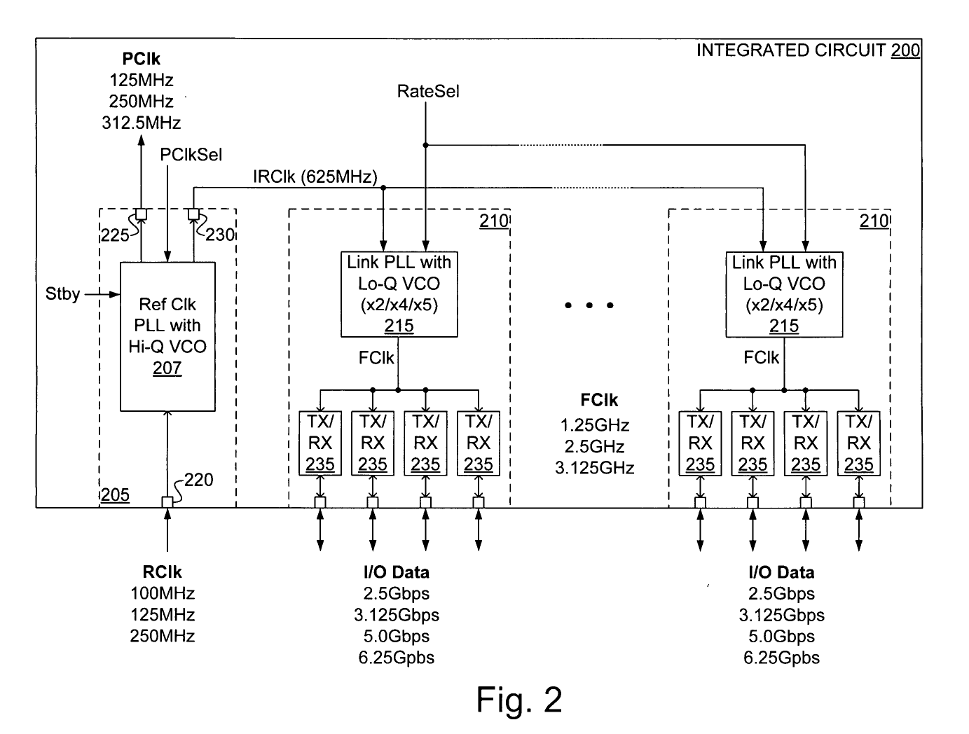

FIG. 2 depicts an integrated circuit (IC) 200 that includes clock synthesis and distribution circuitry in accordance with one embodiment that delivers low-noise transmit and receive clock signals that can be tuned over a broad range of output frequencies. IC 200 includes a clock synthesizer 205 that filters and multiplies an externally generated reference clock signal RClk to produce a low-jitter intermediate reference clock signal IRClk for distribution on IC 200. Additional clock synthesis circuitry within one or more transceiver blocks 210 then multiply intermediate reference clock signal IRClk to develop transmit and receive clock signals.

Clock synthesizer 205 includes a first stage phase-locked loop (PLL) 207 that receives and multiplies reference clock signal RClk to produce intermediate reference clock signal IRClk. Each transceiver block 210 includes a second stage PLL 215 to multiply intermediate reference clock signal IRClk to produce an output clock signal FClk. As compared with the second stage PLLs 215, PLL 207 of synthesizer 205 exhibits a relatively narrow tuning range and is adapted to reject input phase noise from reference clock signal RClk. The second stage PLLs 215 are adapted to operate over a wider frequency range then PLL 207 in terms of the percentage of the center frequency of each PLL's respective VCO.

IC 200 is a multi-channel transceiver in the depicted embodiment, each transceiver block 210 supporting multiple channels. PLL 207 includes a VCO, as does each of PLLs 215. The VCO of PLL 207 differs from those of PLLs 215, however, in that it exhibits a relatively high-Q and a relatively narrow tuning range. As a result, PLL 207 is designed with a relatively narrow (i.e., low) loop bandwidth to produce an intermediate reference clock signal IRClk. In producing signal IRClk, PLL 207 removes much of the phase noise from external reference clock RClk without introducing considerable VCO phase noise. In contrast, each VCO in PLLs 215 is a relatively low-Q oscillator that exhibits a considerable tuning range to support a number of high-speed transmit and receive data rates. PLLs 215 use relatively higher (i.e., wider) loop bandwidths to avoid introducing considerable VCO noise. The following Table 1 correlates a number of common interface standards with the data transfer rates that may be achieved using output clock frequencies provided by the clock multiplication and routing infrastructure of FIG. 2. In Table 1, PCIE stands for PCI Express™, XAUI stands for the 10 Gigabit Attachment Unit Interface. DR Mode in Table 1 refers to whether the data is transferred on both edges of the clock (DDR) or on only one edge (rising or falling) of the clock (SDR).

TABLE 1

| | | | |
|---|---|---|---|
| | | | Data Transfer |
| Standard | DR Mode | FClk Freq | Rate |

| | | | | | |
|---|---|---|---|---|---|
| PCIE | DDR | 1.25 | GHz | 2.5 | Gbps |
| PCIE | SDR | 2.5 | GHz | 2.5 | Gbps |
| Turbo PCIE | DDR | 2.5 | GHz | 5.0 | Gbps |
| Turbo PCIE | DDR | 3.125 | GHz | 6.25 | Gbps |
| XAUI | SDR | 3.125 | GHz | 3.125 | Gbps |
| 2 × XAUI | DDR | 3.125 | GHz | 6.25 | Gbps |

The predominant noise sources in the clock multiplication and distribution system of FIG. 2 are the phase noise of reference clock RClk and the noise introduced by the oscillators in PLLs 215. (In ring-oscillator-based PLLs, as are typically used in PLL 215, the phase noise and supply noise of the VCO is typically much more significant than the noise contributed by the other PLL components.) The clock multiplication and distribution system of IC 200 addresses these noise sources so that output clock signals exhibit low jitter over a broad frequency range. The first PLL 207 exhibits a narrow loop bandwidth and employs a high-Q VCO. PLL 207 thus acts as a low-pass filter to reject input phase noise, while the high-Q VCO introduces little additional noise. The second-stage PLLs 215 exhibit much higher loop bandwidth than PLL 207 and employ relatively low-Q VCOs that can be tuned over a relatively broad frequency range. The wide loop bandwidth of PLLs 215 enables them to reject much of their own VCO-induced noise. Also helpful, the prior multiplication of the reference clock RClk by the PLL 207 limits the degree to which PLLs 215 are required to multiply the intermediate reference clock, and consequently the amount of VCO noise introduced by PLLs 215 by enabling the use of a high loop bandwidth. The characteristics of PLLs 207 and 215 (e.g., the loop bandwidth, VCO quality, and frequency control) may be tuned to achieve a preferred balance of reference-clock and VCO noise rejection to obtain an optimal noise transfer function.

Clock synthesizer 205 includes a reference clock terminal 220, a processor clock node 225, and an intermediate clock node 230. Clock terminal 220 receives external reference clock signal RClk, which is typically supplied via an external oscillator. Depending upon the value provided on a select port PClkSel, PLL 207 may convey a processor clock signal PClk to other circuits (not shown) via clock node 225. In this example, PLL 207 provides one of three available PClk frequencies, 125 MHz, 250 MHz, and 312.5 MHz, to some core logic. Irrespective of the value on select port PClkSel, in this embodiment PLL 207 provides a clean, stable intermediate clock signal IRClk of 625 MHz on node 230 for distribution to each link PLL 215. A second select value provided on select port RateSel determines whether PLLs 215 derive 1.25 GHz, 2.5 GHz, or 3.125 GHz output clock signals FClk from intermediate clock signal IRClk. Each transceiver block 210 employs the selected FClk frequency to establish transmit and receive timing for one or more corresponding transceivers 235. Depending upon the selected mode, transceivers 235 communicate at 2.5 Gbps, 3.125 Gbps, 5.0 Gbps, or 6.25 Gbps. A standby signal Stby to clock synthesizer 205 is asserted in a standby mode to pause distribution of intermediate clock signal IRClk without disabling processor clock PClk. Turning off the intermediate clock signal deactivates each link to save power when the links are not in use. Processor clock PClk can likewise be gated in response to standby signal Stby, or a separate control signal, to allow the processor clock to be paused. These features may be used to support various power management modes, such as those employed in the PCI Express architecture. In other embodiments, one or more of PLLs 215 can be adapted to provide processor clock PClk, in which case different PLLs can deliver different processor-clock frequencies.

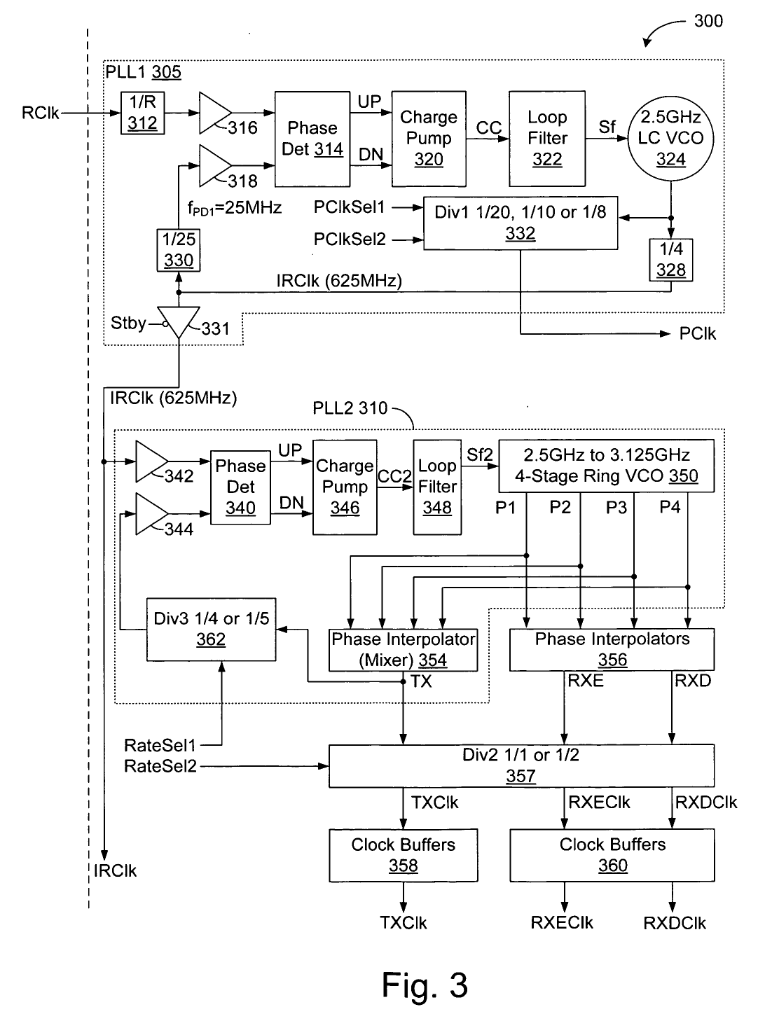

FIG. 3 depicts an IC 300 in accordance with another embodiment. IC 300 is similar to IC 200 of FIG. 2. IC 300 includes a clock synthesizer that derives three clock signals—a transmit clock signal TXClk, a receive edge clock signal RXEClk, and a receive data clock signal RXDClk—from an external reference clock signal RClk. IC 300 accomplishes this derivation using two cascaded PLL stages, including a first PLL 305 and a second PLL 310. Additional second PLLs 310 can be provided to support additional transceiver blocks, but these are omitted here for brevity. Although depicted as single lines, the reference clock paths and the forward and feedback paths of both PLL 305 and PLL 310 may be fully differential to achieve high rejection of supply and substrate noise. Advantageously, the circuitry depicted in FIG. 3 may be formed using standard CMOS processes, and so may be easily integrated.

PLL 305 generates a 625 MHz intermediate clock signal IRClk from any of three potential reference clock frequencies: 100 MHz, 125 MHz, and 250 MHz. To provide this flexibility, PLL 305 includes a frequency divider 312 that can be set to divide reference clock signal RClk by a factor R of four, five, or ten to achieve an effective phase detector input clock frequency FPDI of 25 MHz. The following Table 2 shows the correlation between reference clock frequencies and R, the divisor applied by divider 312. The divisor may be selected via control signals or control registers. Some embodiments detect the reference clock frequency and adjust divider 312 as needed to produce the 25 MHz frequency.

TABLE 2

| RClk | R |
|---|---|
| 100 MHz | 4 |
| 125 MHz | 5 |
| 250 MHz | 10 |

PLL 305 can be adapted to generate intermediate clock signal IRClk from more, fewer, or different reference clock frequencies. For example, one embodiment generates a 625 MHz intermediate clock from the reference clock frequencies of Table 2 and from a 25 MHz reference clock frequency (e.g., R=1). The 25 MHz reference clock can be used, for example, during low-speed testing, such as for wafer sort or burn-in. IC 300 can be adapted to support more, fewer, or different frequencies. One embodiment, for example, supports a 312.5 MHz reference clock RClk, in which case divider 312 may be adapted to divide intermediate clock signal IRClk by 12.5. The basic architecture can be extended to other frequencies by e.g. changing the VCO frequencies and selecting appropriate clock-divider ratios.

The 25 MHz version of reference clock signal RClk is conveyed to a phase detector (or phase-frequency detector) 314 via an optional clock buffer 316. Phase detector 314 compares the phase of the signal from buffer 316 with the phase of a 25 MHz feedback signal from a second optional clock buffer 318 to generate a pair of up and down phase-error signals UP and DN. A charge pump 320 generates a correction current CC in response to the phase-error signals, while a loop filter 322 shapes or filters the correction current CC into a VCO-control signal Sf, which can be e.g. a control voltage, current, or logic stage. A VCO 324 produces a 2.5 GHz clock signal VClk that varies in response to changes in control signal Sf. A pair of frequency dividers 328 and 330 divide clock signal VClk by four and twenty-five, respectively, to provide the 25 MHz feedback signal to buffer 318. As is conventional in PLLs, phase detector 314, charge pump 320, and filter 322 adjusts the frequency and phase of VCO 324 to maintain a fixed phase relationship between the two input signals to phase detector 314, and consequently maintains a fixed frequency and phase relationship between reference clock RClk and intermediate clock IRClk. In one embodiment, the loop bandwidth of PLL 305 is typically set between about 1 and 2 MHz. For a more detailed discussion of PLLs and suitable components for use therein, see “Design of Monolithic Phase-Locked Loops and Clock Recovery Circuits—A Tutorial,” by Behzad Razavi (IEEE Press, 1996), which is incorporated herein by reference. In particular, a widely accepted design principle is to keep the PLL's bandwidth less than or equal to one tenth of the reference frequency at the phase detector. Thus, in this embodiment, this corresponds to a maximum loop bandwidth of 2.5 MHz.

The two most influential noise sources in PLL 305 are the reference clock RClk and VCO 324. Due to the narrow loop bandwidth, PLL 305 acts as a narrow-band tracking filter that blocks most of the phase noise on reference clock signal RClk. (In the present disclosure, “loop bandwidth” may be otherwise defined as the frequency at which the closed-loop gain drops to about 0.707 times the gain at low-frequency.) To minimize VCO noise, VCO 324 is a high-Q oscillator that may be based upon an LC tank circuit (not shown), and thus does not introduce considerable phase noise. VCO 324 has a 2.5 GHz center frequency, a Q of about three to ten, and a tuning range of about five percent. By combining a narrow loop bandwidth with a high-Q VCO, PLL 305 produces a relatively “clean” 625 MHz intermediate clock IRClk.

Frequency divider 332 divides the 2.5 GHz clock signal VClk by 20, 10, or 8 in response to a pair of select signals PCIkSel1 and PClkSel2 to produce 125 MHz, 250 MHz, and 312.5 MHz processor clock signals PClk. The following Table 3 shows the combinations of signals PClkSel1 and PClkSel2 that produce the three available processor-clock frequencies.

TABLE 3

| PClkSel1 | PClkSel2 | Div1 | PClk | |
|---|---|---|---|---|
| 0 | 0 | 1/20 | 125 | MHz |
| 1 | 0 | 1/10 | 250 | MHz |
| 1 | 1 | 1/8 | 312.5 | MHz |

As explained below, the frequency of processor clock signal PClk is adjusted for compatibility with the transmit and receive clock frequencies.

Turning to PLL 310, the 625 MHz intermediate reference clock signal IRClk is conveyed to a phase detector (or phase-frequency detector) 340 via an optional clock buffer 342. Phase detector 340 compares the phase of the signal from buffer 342 with the phase a 625 MHz feedback signal from a second optional clock buffer 344 to generate a pair of up and down phase-error signals UP and DN. A charge pump 346 generates a correction current CC2 in response to the phase-error signals, while a loop filter 348 converts the correction current CC2 into a frequency-control signal Sf2. A VCO 350 produces four phases P1-P4 of a clock signal, the frequencies of which vary in response to changes in control signal Sf2. Relative to VCO 324 in PLL 305, VCO 350 is a low-Q oscillator with a wide tuning range. In the depicted example, VCO 350 operaties at either 2.5 GHz or 3.125 GHz, exhibiting a tuning range of about 25%. Narrower or wider tuning ranges may also be used in other embodiments.

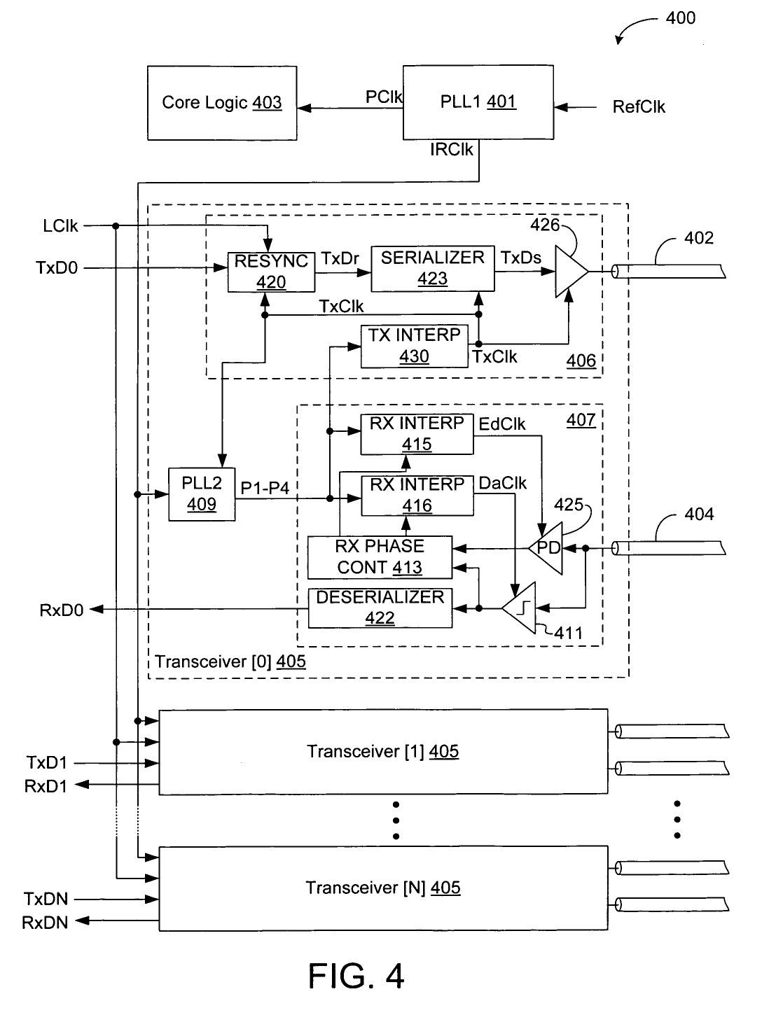

An optional transmit phase interpolator, or phase mixer, 354 selects from and interpolates between a pair of the phase vectors P1-P4 to produce a transmit clock TXClk. Phase vectors P1-P4 are also conveyed from PLL 310 to a pair of additional phase interpolators, illustrated as a single block 356. These phase interpolators combine phase vectors from VCO 350 to produce a receive edge clock RXEClk and a receive data clock RXDClk. A frequency divider 357 then conveys clock signals TX, RXE, and RXD unaltered if a first rate-select signal RateSel2 is asserted (a logic one) and divides each of clock signals TX, RXE, and RXD by two if select signal RateSel2 is deasserted (a logic zero). In either case, divider 357 produces transmit clock signal TXClk and the receive edge and data clock signals RXEClk and RXDClk, respectively. Clock buffers 358 and 360 then buffer the respective transmit and receive clock signals and pass them to respective transmit and receive circuitry (see FIG. 4). Clock architectures in other embodiments generate different types of clock signals to support different types of synchronous circuits. Different embodiments may be used whenever high quality clock signals are required, particularly where the required clock signals may operate over a range of frequencies and are derived from a relatively low-frequency reference clock signal.

The case in which the clock signals are divided by two is discussed below: assume for the moment that divider 357 merely passes the input clock signals. Transmit clock TX is conveyed to a divider 362 that selectively divides the transmit clock frequency by four or five, depending upon the level of select signal RateSel1. Transmit clock TX and receive clocks RXE and RXD are conveyed to divider 357, which selectively divides those signals by one or two, depending upon the level of select signal RateSel2. The following Table 4 shows the combinations of signals RateSel1 and RateSel2 that produce the three available frequencies for transmit clock signal TXClk and receive clock signals RXEClk and RXDClk.

TABLE 4

| RateSel1 | RateSel2 | Div2 | Div3 | TX/RX Clks | |
|---|---|---|---|---|---|
| 0 | 1 | 1/2 | 1/4 | 1.25 | GHz |
| 0 | 0 | 1/1 | 1/4 | 2.5 | GHz |
| 1 | 0 | 1/1 | 1/5 | 3.125 | GHz |

Setting select signals RateSel1 and RateSel2 to zero and one, respectively, causes dividers 357 and 362 to divide their respective input signals by two and four, respectively. PLL 310 thus locks when VCO 350 oscillates at 4×625 MHz, or 2.5 GHz. Divider 357 divides this frequency by two, so the transmit and receive clock signals oscillate at 1.25 GHz. When both select signals RateSel1 and RateSel2 are zero, divider 357 passes the signals from interpolators 354 and 356 unaltered (divided by one) and divider 362 divides transmit clock TX by four. PLL 310 thus locks when VCO 350 oscillates at 2.5 GHz. With divider 357 set to divide by one, the transmit and receive clocks TXClk, RXEClk and RXDClk oscillate at 2.5 GHz. Finally, setting select signals RateSel1 and RateSel2 to one and zero, respectively, causes divider 362 to divide transmit clock signal TX by five and divider 357 to pass clock signals TX, RXE, and RXD unaltered. PLL 310 thus locks when VCO 350 oscillates at 3.125 GHz. Divider 357 is set to divide by one, so transmit and receive clocks TXClk, RXEClk, and RXDClk oscillate at 3.125 GHz. The clock multiplication circuitry of IC 300 can thus support various clock rates, such as to allow compatibility with different standards or to allow for various operational modes with different power-to-performance tradeoffs.

Phase detector 340, charge pump 346, and loop filter 348 adjust the frequency of VCO 350 to maintain a fixed phase relationship between the two input signals to phase detector 340, and consequently the phase relationship between intermediate reference clock IRClk and transmit clock TXClk.

VCO 350 is a low-Q oscillator based upon a ring oscillator (not shown). This type of VCO advantageously offers the desired frequency range and multiple output phases. Unfortunately, low-Q oscillators produce relatively high phase noise. PLL 310 is therefore tuned to exhibit a relatively high loop bandwidth to lower the noise contribution of VCO 350. In this embodiment, PLL 310 exhibits a loop bandwidth of between about 40 and 62.5 MHz. Increasing the loop bandwidth renders PLL 310 more susceptible to input noise (i.e., phase noise on intermediate reference clock signal IRClk). Recall, however, that PLL 305 is adapted to remove the jitter on reference clock RClk, leaving intermediate reference clock IRClk relatively clean. The loop bandwidth of PLL 310 can thus be increased for improved VCO noise immunity. Also important, the loop bandwidth of a PLL is limited to about 10% of the input frequency, so the pre-multiplication of the reference clock signal by PLL 305 to 625 MHz facilitates the increased bandwidth for PLL 310 of up to 62.5 MHz. For a more detailed discussion of the impact of loop bandwidth on VCO noise, see the above-incorporated Razavi reference.

In addition to the aforementioned, PLL 305 includes a buffer 331. Buffer 331 blocks intermediate reference clock IRClk in response to a standby signal Stby that is asserted to save power by disabling the distribution of intermediate clock signal IRClk without disabling processor clock PClk.

FIG. 4 depicts an IC 400 in accordance with an embodiment that employs a two-stage clocking architecture of the type described above in connection with FIGS. 2 and 3. IC 400 includes a PLL 401, some core logic 403, and N+1 transceivers with associated serial link channels. For brevity, the following discussion is limited to just one of a number of transceivers 405 and an associated pair of serial communication channels, an outgoing channel 402 and an incoming channel 404.

PLL 401 is similar or identical to PLL 305 of FIG. 3, and generates a clean intermediate reference clock signal IRClk and a processor clock PClk in the manner discussed above. Core logic 403 is e.g. a graphics processor. Transceiver 405 includes a transmit section 406, a receive section 407, and a phase-lock loop (PLL) 409 shared by both transmit and receive sections 405 and 407. PLL 409 approximates PLL 310 of FIG. 3, though the boundaries are drawn in FIG. 4 to exclude the transmit phase interpolator. Each transceiver 405 includes PLL 409 in the depicted embodiment, but one PLL 409 can also be shared among a plurality of transceivers. In the latter case, transmit clock TxClk and phase vectors P1-P4 can be shared, each transceiver deriving edge and data receive clocks from the respective received signal using the phase vectors. In still other embodiments, the phase vectors alone are shared, in which case one or more of the phase vectors can be used to generate the transmit clocks.

Receive section 407 is of a well-known type, and is thus not described in detail. In brief, receive section 407 includes a phase detector 425 and a sampler 411, each of which samples received data from channel 404. Phase detector 425 provides an output signal to a receiver phase controller 413, which controls the sample timing of the received signal via a pair of phase interpolators 415 and 416 that derive edge and data clocks EdClk and DaClk, respectively, by combining selected ones of a plurality of differently phased reference clocks P1-P4 from PLL 409. Sampler 411, thus properly timed, samples the incoming data and provides the resulting sampled data to a deserializer 422 for conversion to parallel input data RxD0, and to phase controller 413.

Transmit section 406 is also of a well-known type, and conventionally includes a resynchronizer 420 that re-times parallel transmit data TxDO timed to a local clock LClk to transmit clock TxClk. The resulting re-timed parallel data TxDr is then fed to a serializer 423. Serial transmit data TxDs from serializer 423 is then conveyed to a transmitter 426 for transmission over channel 402. A transmit phase interpolator 430 coupled to the output of PLL 409 is optionally included to match the delay through the PLL feedback loop to the delay through the receive interpolators. In one embodiment, resynchronizer 420 is of a type described in U.S. patent application Ser. No. 10/282,531 entitled “Method and Apparatus for Fail-Safe Resynchronization with Minimum Latency,” which is incorporated herein by reference. An article entitled “Equalization and Clock Recovery for a 2.5-10-Gb/s 2-PAM/4-PAM Backplane Transceiver Cell,” by Jared L. Zerbe, et al. (IEEE JSSC, December 2003) details an example of a transceiver similar to transceiver 405 but employing a different clock architecture.

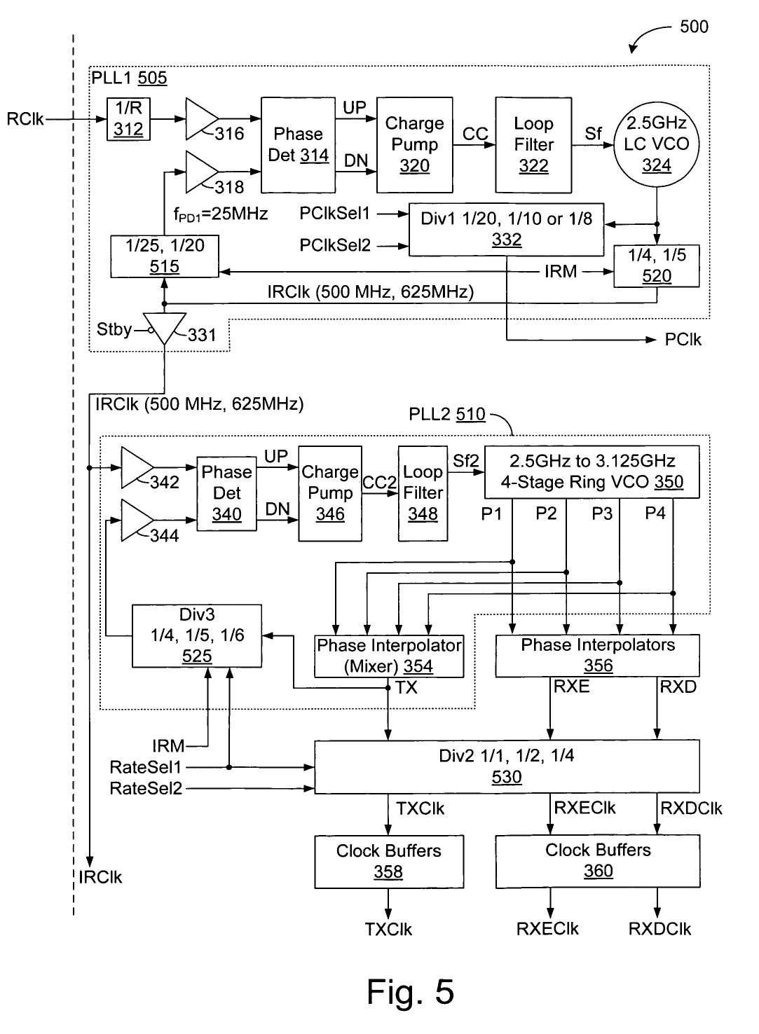

The foregoing embodiments can be adapted for use with other communication schemes. FIG. 5 depicts an IC 500 in accordance with an embodiment extended to derive 750 MHz, 1.5 GHz, and 3 GHz clock signals for SATA interfaces. At present, SATA data rates are e.g. 1.5 Gbps (SATAI), 3.0 Gbps (SATAII) and 6.0 Gbps (SATAIII). IC 500 is similar to IC 300 of FIG. 3, like-labeled elements being the same or similar. Detailed discussions of like-labeled elements are omitted for brevity. IC 500 derives transmit and receive clock signals TXClk, RXEClk, and RXDClk using cascaded PLL stages 505 and 510. These stages are similar to stages 305 and 310 of IC 300, but the number of supported clock rates is increased.

Referring first to PLL 505, the fixed-ratio dividers of PLL 305 are replaced with a pair of selectable dividers 515 and 520. Dividers 515 and 520 can be set to divide by twenty-five and four, respectively, to produce a 625 MHz intermediate clock IRClk in the manner described above; alternatively, dividers 515 and 520 can be set to divide by twenty and five, respectively, to produce a 500 MHz intermediate clock IRClk in support of SATA operational modes. The intermediate-reference frequency can be selected using an internal or external mode-select signal IRM.

Turning to PLL 510, the selectable dividers of PLL 310 are replaced with dividers 525 and 530, each of which offers the selection of an additional factor. Divider 525 is extended to divide signal TX by six, thus fixing the oscillation frequency of VCO 350 at 3.0 GHz when intermediate frequency IRClk is at 500 HMz (i.e., 6×500 MHz=3 GHz). The divide-by-six setting of divider 525 is used in each SATA mode, and can be selected using the same mode signal used to control the output of PLL 505 to 500 MHz.

The transmit and receive clock rates supportive of SATA interfaces are 750 MHz, 1.5 GHz, and 3.0 GHz. Divider 530 selectively divides the 3.0 GHz output from VCO 350 in the SATA modes by four, two, or one to achieve these respective rates for clock signals TXClk, RXEClk, and RXDClk. The following Table 5 shows the combinations of signals IRM, RateSel1, and RateSel2 that produce the six available frequencies for transmit clock signal TXClk and receive clock signals RXEClk and RXDClk in the embodiment of FIG. 5.

TABLE 5

| IRM | RateSel1 | RateSel2 | Div2 | Div3 | TX/RX Clks | |
|---|---|---|---|---|---|---|
| 0 | 0 | 1 | 1/2 | 1/4 | 1.25 | GHz |
| 0 | 0 | 0 | 1/1 | 1/4 | 2.5 | GHz |
| 0 | 1 | 0 | 1/1 | 1/5 | 3.125 | GHz |
| 1 | 1 | 1 | 1/4 | 1/6 | 750 | MHz |
| 1 | 0 | 1 | 1/2 | 1/6 | 1.5 | GHz |
| 1 | 0 | 0 | 1/1 | 1/6 | 3.0 | GHz |

Thus, depending on the selected mode, IC 500 can develop six different transmit and receive clock frequencies in support of six different communication schemes. SATA communication schemes can employ rising and falling clock edges (DDR), so the 750 MHz, 1.5 GHz, and 3.0 GHz clock signals can support 1.5 Gbs, 3.0 Gbs, and 6.0 Gbs SATA data rates, respectively.

An output of the design process for an integrated circuit, or a portion of an integrated circuit, may be a computer-readable medium (e.g., a magnetic tape or an optical or magnetic disk) encoded with data structures or other information defining circuitry that may be physically instantiated as an integrated circuit or portion of an integrated circuit. These data structures are commonly written in Caltech Intermediate Format (CIF) or GDSII, a proprietary binary format. Those of skill in the art of mask preparation can develop such data structures from schematic diagrams of the type detailed above.

In the foregoing description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. In any case, whether a given signal is an active low or an active high will be evident to those of skill in the art.

While the present invention has been described in connection with specific embodiments, variations of these embodiments will be obvious to those of ordinary skill in the art. For example:
1. one or more of the PLLs can be replaced with a delay-locked loop (DLL) or a multiplying delay-locked loop (M-DLL);
2. one or more VCOs in systems in accordance with the foregoing embodiments can be replaced with controllable delay lines;
3. current-controlled elements can be used in place of one or more of the voltage-controlled elements;
4. the VCOs can be provided with voltage regulators to provide an extra measure of isolation between the supply noise and VCO output jitter; and
5. some systems that support both DDR and SDR may simply ignore one type of edge (rising or falling) in SDR mode to achieve a half data-rate mode compared to the DDR mode, and additional edges can be ignored to support even lower fractional data rates.
   Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. Section 112.

What is claimed is:

1. A frequency synthesizer comprising:
a. a reference clock node adapted to receive a reference clock signal of a reference-clock frequency;
b. a first phase-locked loop having:
i. a first phase detector having a first phase-detector input node coupled to the reference clock node, a first feedback node adapted to receive a first feedback signal, and a first phase-detector output node, wherein the first phase detector is adapted to generate a first phase error signal in response to a first phase difference between the reference clock signal and the first feedback signal;
ii. a first clock source having a first clock source input node, coupled to the first phase-detector output node, and a first clock source output node, wherein the first clock source is adapted to generate a first phase-locked clock signal of a second frequency greater than the reference clock frequency;
iii. a first feedback path extending between the first clock source output node and the first feedback node;
iv. wherein the first phase-locked loop exhibits a first loop bandwidth;
c. a second phase-locked loop having:
i. a second phase detector having a second phase-detector input node coupled to the reference clock node, a second feedback node adapted to receive a second feedback signal, and a second phase-detector output node, wherein the second phase detector is adapted to generate a second phase error signal in response to a second phase difference between the first phase-locked clock signal and the second feedback signal;
ii. a second clock source having a second clock source input node, coupled to the second phase-detector output node, and a second clock source output node, wherein the second clock source is adapted to generate a second phase-locked clock signal of a third frequency greater than the second frequency;
iii. a second feedback path extending between the second clock source output node and the second feedback node;
iv. wherein the second phase-locked loop exhibits a second loop bandwidth greater than the first loop bandwidth.

2. The frequency synthesizer of claim 1, wherein the first phase-locked loop comprises an LC tank oscillator.

3. The frequency synthesizer of claim 1, wherein the second frequency is at least twice the first frequency.

4. The frequency synthesizer of claim 1, wherein the third frequency is at least twice the second frequency.

5. The frequency synthesizer of claim 1, wherein at least one of the first and second clock sources comprises a circuit selected from the group consisting of a voltage-controlled oscillator and a variable delay line.

6. The frequency synthesizer of claim 1, wherein the first loop bandwidth is less than 0.2% of the second frequency.

7. The frequency synthesizer of claim 6, wherein the second loop bandwidth is at least ten times the first loop bandwidth.

8. The frequency synthesizer of claim 1, wherein the second frequency is tunable over a first range and the second frequency is tunable over a second range greater than the first range.

9. The frequency synthesizer of claim 8, wherein the first range is less than 10% and the second range is greater than 15%.

10. The frequency synthesizer of claim 1, the second feedback path including a selectable divider.

11. The frequency synthesizer of claim 10, wherein the selectable divider is adapted to divide the second frequency by a selected one of a plurality of integers.

12. An integrated circuit comprising:
a. a reference clock terminal adapted to receive a reference-clock signal of a reference-clock frequency;
b. a first locked-loop circuit having:
i. a first reference clock node coupled to the reference-clock terminal and adapted to receive the reference-clock signal; and
ii. an intermediate clock node;
iii. wherein the first locked-loop circuit is adapted to exhibit a first tuning range and a first loop bandwidth, and is adapted to provide an intermediate clock signal on the intermediate clock node; and
c. a second locked-loop circuit having:
i. a second reference clock node coupled to the intermediate clock node and adapted to receive the intermediate clock signal; and
ii. an output clock node;
iii. wherein the second locked-loop circuit is adapted to exhibit a second tuning range greater than the first tuning range and a second loop bandwidth greater than the first loop bandwidth, and is adapted to provide an output clock signal on the output clock node.

13. The integrated circuit of claim 12, wherein the first locked-loop circuit is adapted to multiply the reference clock frequency by a factor to produce the intermediate clock signal.

14. The integrated circuit of claim 13, wherein the second locked-loop circuit is adapted to multiply the intermediate clock frequency by a second factor to produce the output clock signal.

15. The integrated circuit of claim 12, wherein the second locked-loop circuit is adapted to multiply the intermediate clock frequency by a factor to produce the output clock signal.

16. The integrated circuit of claim 12, wherein the first locked-loop circuit comprises an LC tank circuit.

17. The integrated circuit of claim 12, wherein the second loop bandwidth is greater than twice the first loop bandwidth.

18. The integrated circuit of claim 12, wherein the first tuning range is less than half the second tuning range.

19. A method comprising:
a. providing a reference clock signal to an integrated circuit;
b. multiplying the reference clock signal by a first factor to obtain an intermediate clock signal;
c. distributing the intermediate clock signal to a plurality of nodes on the integrated circuit; and
d. multiplying, at each of the plurality of nodes, the intermediate clock signal by a second factor to obtain a plurality of output clock signals.

20. The method of claim 19, further comprising periodically pausing (d) while multiplying the reference clock signal by the first factor.

21. The method of claim 20, wherein further comprising pausing (c) while multiplying the reference clock signal by the first factor.

22. The method of claim 20, further comprising multiplying the reference clock signal by a third factor to obtain a system clock.

23. The method of claim 22, further comprising distributing the system clock on the integrated circuit.

24. A clock synthesizer comprising:
a. a reference clock node for receiving a reference clock signal;
b. means for multiplying the reference clock signal by a first factor to obtain an intermediate clock signal;
c. means for distributing the intermediate clock signal to a plurality of nodes on the integrated circuit; and
d. means for multiplying, at each of the plurality of nodes, the intermediate clock signal by a second factor to obtain a plurality of output clock signals.

25. The clock synthesizer of claim 24, wherein the means for multiplying the reference clock signal by the first factor is adapted to select from among a plurality of first factors.

26. The clock synthesizer of claim 24, wherein the means for multiplying the intermediate clock signals by the second factor is adapted to select from among a plurality of second factors.

27. An integrated circuit comprising:
a. a reference node receiving a reference clock signal having a reference clock frequency;
b. a first phase-locked loop (PLL) having:
i. a first phase detector having a first phase-detector input node coupled to the reference clock node, a second phase-detector input node, and a first phase-detector output node; and
ii. a first voltage-controlled oscillator having a first control terminal coupled to the first phase-detector output node and an intermediate clock node coupled to the second phase-detector input node;
iii. wherein the first voltage-controlled oscillator provides on the intermediate clock node an intermediate clock signal having an intermediate clock frequency greater than the reference clock frequency; and
c. a second phase-locked loop (PLL) having:
i. a second phase detector having a third phase-detector input node coupled to the intermediate clock node, a fourth phase-detector input node, and a second phase-detector output node; and
ii. a second voltage-controlled oscillator having a second control terminal coupled to the second phase-detector output node and an output clock node coupled to the fourth phase-detector input node;
iii. wherein the second voltage-controlled oscillator provides on the output clock node an output clock signal having an output clock frequency greater than the intermediate clock frequency.

28. The integrated circuit of claim 27, wherein the first voltage-controlled oscillator exhibits a first loop bandwidth less then ten percent of the reference clock frequency.

29. The integrated circuit of claim 28, wherein the first loop bandwidth is substantially less than ten percent of the reference clock frequency.

30. The integrated circuit of claim 28, wherein the second voltage-controlled oscillator exhibits a second loop bandwidth greater than the first loop bandwidth.

31. The integrated circuit of claim 30, wherein the second loop bandwidth is about ten percent of the frequency of the intermediate clock signal.

32. An integrated circuit comprising:
a. a reference node receiving a reference clock signal having a reference clock frequency;
b. a first phase-locked loop (PLL) having a first controlled oscillator providing an intermediate clock signal having an intermediate clock frequency greater than the reference clock frequency; and
c. a second phase-locked loop (PLL) having a second controlled oscillator deriving, from the intermediate clock signal, an output clock signal having an output clock frequency greater than the intermediate clock frequency.

33. The integrated circuit of claim 32, wherein the first controlled oscillator exhibits a first loop bandwidth less then ten percent of the reference clock frequency.

34. The integrated circuit of claim 33, wherein the first loop bandwidth is substantially less than ten percent of the reference clock frequency.

35. The integrated circuit of claim 33, wherein the second controlled oscillator exhibits a second loop bandwidth greater than the first loop bandwidth.

36. The integrated circuit of claim 32, wherein the second loop bandwidth is about ten percent of the frequency of the intermediate clock signal.

37. The integrated circuit of claim 32, wherein at least one of the controlled oscillators is a voltage-controlled oscillator.

38. A computer-readable medium having stored thereon a data structure defining a clock distribution circuit, the data structure comprising:
a. first data representing a reference node receiving a reference clock signal having a reference clock frequency;
b. second data representing a first phase-locked loop (PLL) having a first controlled oscillator providing an intermediate clock signal having an intermediate clock frequency greater than the reference clock frequency; and
c. third data representing a second phase-locked loop (PLL) having a second controlled oscillator deriving, from the intermediate clock signal, an output clock signal having an output clock frequency greater than the intermediate clock frequency.

39. The computer-readable medium of claim 38, wherein the second data represent the first controlled oscillator as exhibiting a first loop bandwidth less then ten percent of the reference clock frequency.

40. The computer-readable medium of claim 39, wherein the first loop bandwidth is substantially less than ten percent of the reference clock frequency.

41. The computer-readable medium of claim 39, wherein the third data represent the second controlled oscillator as exhibiting a second loop bandwidth greater than the first loop bandwidth.

42. The computer-readable medium of claim 39, wherein at least one of the controlled oscillators is a voltage-controlled oscillator.
